(19) United States
(12) Patent Application Publication
(10) Pub. No.: US 2017/0243096 A1
(43) Pub. Date: Aug. 24, 2017

(54) METHOD AND APPARATUS FOR MULTI-DIMENTIONAL CODE STORAGE AND TRANSFER SYSTEM

(71) Applicants: Jeff Kotowski, Nevada, CA (US); Charles Cai, Mather, CA (US)

(72) Inventors: Jeff Kotowski, Nevada, CA (US); Charles Cai, Mather, CA (US)

(21) Appl. No.: 15/049,145

(22) Filed: Feb. 22, 2016

(51) Int. Cl. G06K 19/06; G11C 17/14; G06K 7/14

(52) U.S. Cl. CPC G06K 19/0614; G06K 19/06112; G06K 7/1443; G06K 19/06037; G11C 17/143

(57) ABSTRACT

Embodiments disclosed herein describe a multi-dimensional code storage and transfer system. The system gets electrical power from the flash light of a typical smart device, and displays a time-varying multi-dimensional code which can be captured and decoded by the smart device. The system can be made by printed electronics technology.

### CROSS REFERENCE TO RELATED APPLICATIONS

Not applicable.

### FIELD OF INVENTION

This invention relates to a low cost small form factor multi-dimensional code storage and transfer system for product authentication and anti-counterfeiting.

### BACKGROUND OF INVENTION

Counterfeit goods are goods made or sold under another's brand name without the brand owner's authorization and are often of inferior quality. Counterfeit products exist in virtually every area, including food, beverages, wine, perfumes, clothes, shoes, pharmaceuticals, electronics and cosmetics. The spread of counterfeit goods is worldwide, and in 2015 the Organisation for Economic Co-operation and Development (OECD) estimated the global value of all counterfeit goods reached $1.77 trillion and make up 5 to 7% of world trade. As a result of this increasing risk, the anti-counterfeit packaging market is projected to witness significant growth in the future with the increasing popularity of the benefits of authentication technologies embedded in packaging. According to a study done by MarketsandMarkets, the anti-counterfeit packaging market size is projected to grow from USD 82.05 Billion in 2015 to reach USD 153.95 Billion by 2020, at an estimated CAGR of 13.41%.

Currently there are many types of anti-counterfeit technologies available on the market, but they all have some shortcomings in one way or the other. For example, people use “Overt” technologies such as printed logo, holograms, barcode or QR (Quick Response) code to authenticate products, but they are easy to be copied. For example, people use “Covert” technologies such as invisible printing, laser coding or digital watermarks to authenticate products, but they are hidden from most product end users so can not be verified by them. For example, people use “Forensic” technologies such as chemical taggants to authenticate products, but they need sophisticated equipment which are not available for most product end users. Recently, people use RFID (Radio Frequency Identification) or NFC (Near Field Communication) technology to authenticate products, but it also have many shortcomings. First it needs special tool (“RF Reader”) or a special smartphone which has equipped with NFC capability, but only very small percentage of smartphones on market have this capability. This means most product end users can not authenticate the product easily. Secondly this technology needs antenna to get power and to communicate data. The antenna has big size which prevents products of small form factor to use this technology. Also products with conductive surface (such as metal package) will interfere the electric-magnetic field of the antenna so can not use this technology either. (Adding another isolation layer between the products' conductive surface and antenna will enable this technology but add cost and compromise the performance.) Thirdly, this technology is expensive since it needs antenna and high speed electronic circuits to transmit and receive the RF signal at high speed (13.56 MHz).

For a long time people have desired a good anti-counterfeit technology which should have following characteristics: first it should be very hard to copy or duplicate by people who are trying to counterfeit. Secondly it should let most product end users very easy to authenticate by using conveniently available tools such as smart device. A smart device is defined as any device that has photographic capability combined with intelligence and an internet connection. A smart device includes, but is not limited to, a smartphone, a tablet, a laptop computer, many music players and even some cameras. Third it should have small form factor and light weight so can be applied to almost all products as part of the their product packages. Last but not least, it should have very low cost so people can afford to use it everywhere.

This invention discloses methods and apparatuses for a multi-dimensional code storage and transfer system. It can be used together with a typical smart device with video capture capability to authenticate a product. It can store and transmit time-varying code so it is very difficult to duplicate by people who are trying to counterfeit. It has small form factor and can be applied to the surface of almost any kind of product. It uses printed electronics technology so its cost is very low.

### SUMMARY

The methods and apparatuses disclosed by this invention describe a multi-dimensional code storage and transfer system. It can store and transmit time-varying multi-dimensional code which can be captured by a typical smart device to authenticate a product. It also gets power from the smart device flash light so no battery nor antenna is needed. The system can be printed using printed electronics technology so its cost is very low. The system has small form factor and is flexible, so can be applied to the surface of almost any kind of product.

The typical application of this invention can be a low cost and small form factor packaging label for product authentication and product anti-counterfeiting. It can also be used as a small form factor packaging label to contain product description and usage instruction.

### BRIEF DESCRIPTION OF THE DRAWINGS

Embodiments of the invention relating to both structures and methods of operation may best be understood by referring to the following descriptions and accompanying drawings:

FIG. 1 shows an embodiment of this invention;

FIG. 2A shows an embodiment of a control block of this invention;

FIG. 2B shows the waveforms for the embodiment in FIG. 2A;

FIG. 3A˜3E show an embodiment of a display block of this invention which displays time-varying multi-dimensional code;

FIG. 3F shows the waveform for the embodiment in FIG. 3A˜3E;

FIG. 4 shows an embodiment of a display block of this invention;

FIG. 5 shows another embodiment of this invention which has an event sensing block;

FIG. 6 shows an embodiment of an event sensing block of this invention;

FIG. 7 shows another embodiment of a control block of this invention which can change code depending on the result from a event sensing block;

FIG. 8 shows another embodiment of this invention.

### DETAILED DESCRIPTION

A good anti-counterfeit technology should have characteristics of: difficult to counterfeit; no need to use special tool; small, light and flexible so can be applied to the surface of most products; low cost. The anti-counterfeit technologies currently available on market such as NFC or QR code technology all have their own shortcomings. This invention discloses methods and apparatuses for a multi-dimensional code storage and transfer system made by printed electronics technology. It can be used for product authentication and anti-counterfeit.

Printed electronics (also called “organic electronics” or “plastic electronics”) technology is a set of printing methods used to create electrical devices on various (often flexible) substrates. Printing typically uses common printing equipment suitable for defining patterns on material, such as screen printing, flexography, gravure, offset lithography, and inkjet. During these low cost processes, electrically functional electronic inks are deposited on the substrate, creating active or passive devices, such as solar cells; thin film transistors; OLED (Organic LED); electrochromic displays; e-ink displays; capacitors; coils; resistors. Both organic materials (such as conjugated polymers or conductive polymers) and inorganic materials (such as silver or gold nanoparticles) are used for printed electronics. Printed electronics allows the use of flexible substrates such as flexible foil and paper, which lowers production costs and allows fabrication of mechanically flexible circuits.

The methods and apparatuses disclosed by this invention describe a multi-dimensional code storage and transfer system made by printed electronics technology. The system comprises a printed display block to display a time-varying multi-dimensional code, which can be captured by a typical smart device using its video capture feature. The smart device can analyze the captured images and decode the code for product authentication and anti-counterfeit. The system also comprises a printed photovoltaic block which can generate electric power for the system from the flash light coming from the smart device. Since the system uses printed electronics technology to display a time-varying multi-dimensional code, it is very difficult to counterfeit. The system only needs a smart device with a flash light and video capture feature, so it can be widely used by almost all the people who have a typical smart device. The system is made by printed electronics technology, so it is lightweight, small, flexible and can be applied to curved surface of many products. And the printed electronics technology can make the system at very low cost.

In following paragraphs embodiments of this invention will be shown for example to explain the concept of the invention in detail. However it should be understood that it is not intended to limit the invention to the particular apparatuses and methods disclosed, but on the contrary, the intention is to cover all the apparatus and method modifications, equivalents and alternatives falling within the scope of the invention defined by the appended claims.

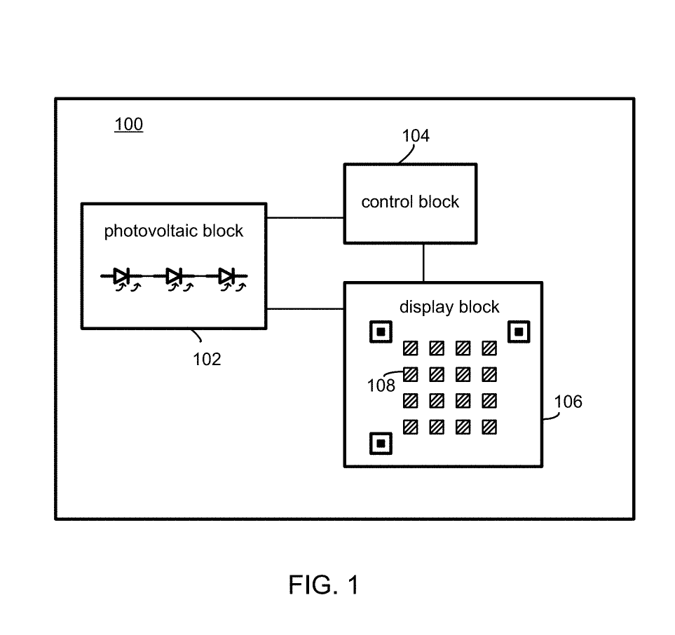

FIG. 1 shows an embodiment of a multi-dimensional code storage and transfer system of this invention. In FIG. 1, a multi-dimensional code storage and transfer system 100 includes a photovoltaic block 102, a control block 104 and a display block 106. The photovoltaic block 102 is coupled to the control block 104 and the display block 106. The control block 104 is also coupled to the display block 106. The display block 106 includes a display element 108 and optionally more similar display elements. In this exemplary embodiment the display block 106 includes 16 display elements forming a 4 by 4 array for sake of illustration, but in other embodiments the display block 106 can include any number of display elements formed in any shape of array. Each display element of the display block 106 can represent a high or low state by showing dark or white color. One row of these display elements forms a one dimensional code, and multiple rows of these display elements forms a two-dimensional code. In addition to this, each display element can represent more states by showing different colors such as red, blue, yellow or green, or different brightness. So multiple rows of these display elements can form a multi-dimensional code. Additionally, the display block 106 disclosed by this invention adds time as one more dimension to the code. The display elements of the display block 106 can change their states at different times, to form a time-varying multi-dimensional code. In FIG. 1, the photovoltaic block 102 includes one or more printed solar cells and generates electric power for the control block 104 and the display block 106 when receiving flash light from a smart device. The control block 104 can be made using printed electronic devices such as printed OTFT (Organic Thin Film Transistor), printed resistors and printed conducting wires. The display block 106 can be made using OLED (Organic Light Emitting Diode), electrochromic display, e-ink display or electroluminescent display technology. The control block 104 controls the display block 106 to display a time-varying multi-dimensional code. A smart device can capture the time-varying code and decode it by analyzing the captured images.

Making the multi-dimensional code time varying has many advantages. It can make the counterfeit very difficult because it needs sophisticated printed electronic technology. Also a time-varying multi-dimensional code can carry a lot more data, for a given physical display size, than a conventional time-invariant multi-dimensional code. So a time-varying multi-dimensional code disclosed by this invention can be used at places where the allowed physical display size is too small to put any conventional QR code. Also a time-varying multi-dimensional code disclosed by this invention can use very small physical display size to transfer a big file which can be a voice file, an image file or even a video file, which is not possible by using conventional QR code.

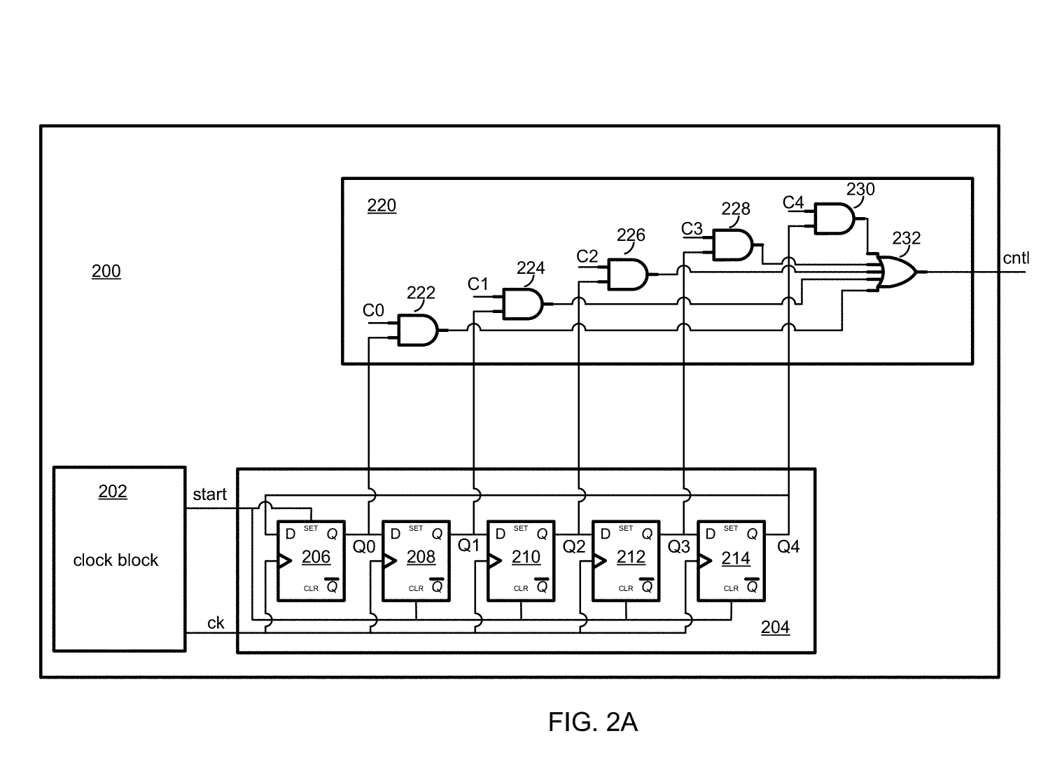

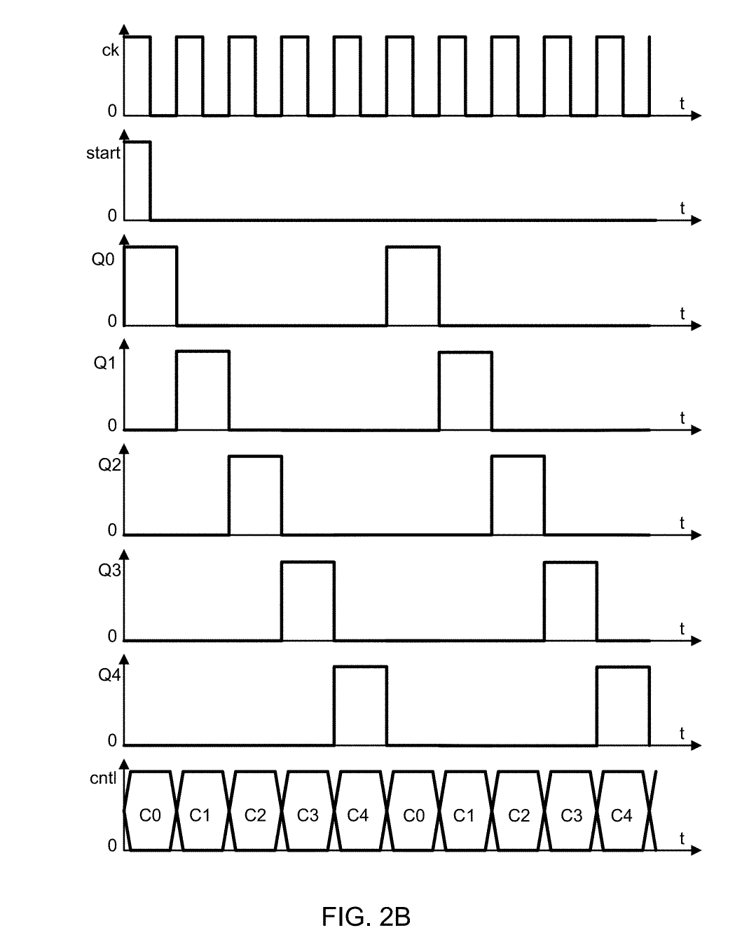

FIG. 2A shows an embodiment of a control block of this invention. In FIG. 2A, a control block 200 includes a clock bloc 202, a ring counter block 204 and a code block 220. The ring counter block 204 includes a D Flip-Flop 206, a D Flip-Flop 208, a D Flip-Flop 210, a D Flip-Flop 212 and a D Flip-Flop 214. The Q terminal of the D Flip-Flop 206 is coupled to signal Q0, which is also coupled to the D terminal of the D Flip-Flop 208. The Q terminal of the D Flip-Flop 208 is coupled to signal Q1, which is also coupled to the D terminal of the D Flip-Flop 210. The Q terminal of the D Flip-Flop 210 is coupled to signal Q2, which is also coupled to the D terminal of the D Flip-Flop 212. The Q terminal of the D Flip-Flop 212 is coupled to signal Q3, which is also coupled to the D terminal of the D Flip-Flop 214. The Q terminal of the D Flip-Flop 214 is coupled to signal Q4, which is also coupled to the D terminal of the D Flip-Flop 206. The clock bloc 202 generates a signal start, which is coupled to the SET terminal of the D Flip-Flop 206, and the CLR terminal of the D Flip-Flop 208, the D Flip-Flop 210, the D Flip-Flop 212 and the D Flip-Flop 214. The clock bloc 202 also generates a clock signal ck, which is coupled to the input clock terminals of the D Flip-Flop 206, the D Flip-Flop 208, the D Flip-Flop 210, the D Flip-Flop 212 and the D Flip-Flop 214. The code block 220 includes a AND gate 222, a AND gate 224, a AND gate 226, a AND gate 228, a AND gate 230 and a OR gate 232. The outputs of the AND gate 222, the AND gate 224, the AND gate 226, the AND gate 228 and the AND gate 230 are coupled to the inputs of the OR gate 232. The output of the OR gate 232 is coupled to a signal cntl. The signals Q0, Q1, Q2, Q3 and Q4 are coupled to the inputs of the AND gate 222, the AND gate 224, the AND gate 226, the AND gate 228 and the AND gate 230. A code signal C0 is coupled to the input of the AND gate 222. A code signal C1 is coupled to the input of the AND gate 224. A code signal C2 is coupled to the input of the AND gate 226. A code signal C3 is coupled to the input of the AND gate 228. A code signal C4 is coupled to the input of the AND gate 230. The code signals C0 to C4 are logic high or low signals, which can come from ROM (Read Only Memory) memory, EPROM (Erasable Programmable Read Only Memory) or programmable fuse memory (which can be programmed by using laser zap or high current).

FIG. 2B shows the waveforms for the embodiment in FIG. 2A. As shown in FIG. 2A and FIG. 2B, the clock block 202 generates a signal start and a clock signal ck when it is powered up. The signal start is a single pulse and it sets the signal Q0 to be high and the signals Q1, Q2, Q3 and Q4 to be low at the beginning. After the signal start goes low, the first rising edge of the clock signal ck will set the Q0 to be low and the Q1 to be high. The second rising edge of the clock signal ck will set the Q1 to be low and the Q2 to be high. The continuing rising edges of the clock signal ck will eventually make the a logic high pulse circulating from Q0 to Q4 sequentially. When Q0 is high, the signal cntl will be equal to the code signal C0. And when Q1, Q2, Q3 or Q4 is high, the signal cntl will be equal to the code signal C1, C2, C3 or C4 respectively. The signal cntl will control the state of a display element of the display block. The frequency of the clock signal ck will determine how fast the state of the display element is changing. Since the state of the display element is captured by a smart device using its video capture feature, the state can not change faster than the Nyquist rate which is half of the sampling rate of the smart device to avoid aliasing. A typical smart device currently has a sampling rate of 20 to 60 fps (frame per second), so the period of the clock signal ck can be around 33 to 100 milliseconds. The period can be shorter if the smart device has a higher sampling rate. Even so, longer period can accommodate a smart device with a lower sampling rate, and can have more margin for the smart device to sample.

In this exemplary embodiment shown in FIG. 2A and FIG. 2B, for sake of illustration the code block 220 only have 5 different code signals so the signal cntl can only control a display element to display 5 different states, but in other embodiments the code block 220 can have any number of code signals. More code signals means more data can be transferred and also more time needed to transfer. In other embodiments a display element can also show different brightness to represent different states, and the signal cntl can have different voltage levels to control the display element to show different brightness. In other embodiments a display element can also show different colors to represent different states, so multiple signal cntl can couple to the same display element and each can control the display element to show a different color respectively.

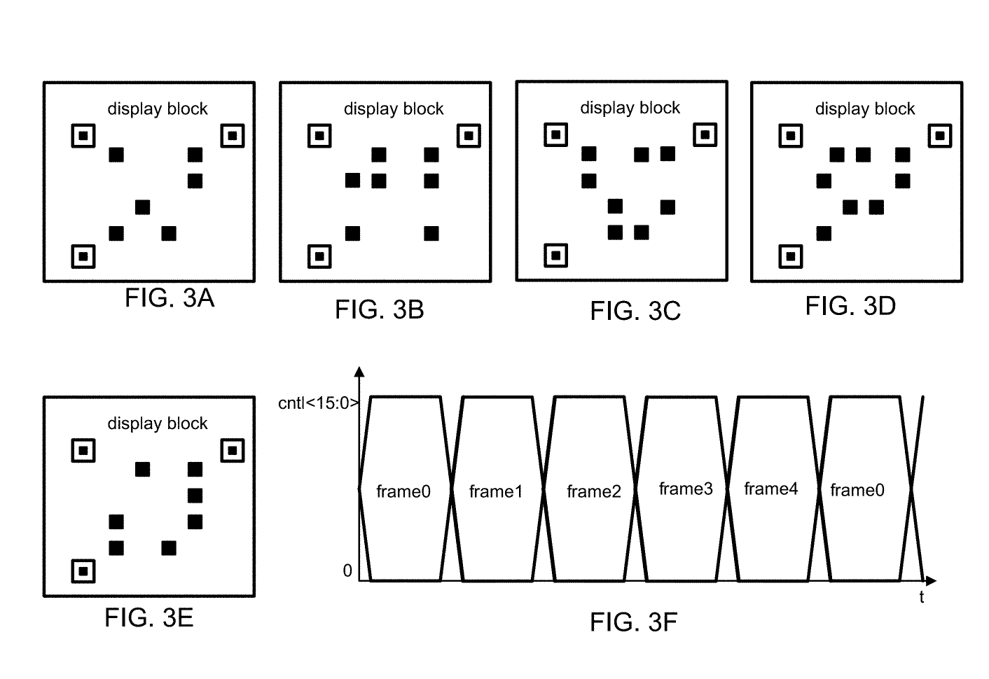

Each signal cntl in FIG. 2A controls a display element to display different states at different times, and multiple signal cntl will control multiple display elements in a display block to display different multi-dimensional codes at different times as shown in FIG. 3A˜3F. In this exemplary embodiment shown in FIG. 3A˜3F, for sake of illustration the display block has only 16 display elements and each element can display a different state at 5 different times. But in other embodiments the display block can have any number of display elements and each element can display a different state at any number of times. In each of FIG. 3A˜3E, the display block display a different multi-dimensional code which corresponds to a different frame of signals cntl<15:0> in FIG. 3F. The display block displays different frames of code at different times to transfer a time-varying multi-dimensional code. Since the time-varying multi-dimensional code is composed by many different frames of code ordered in time sequence, a start frame is usually needed to indicate the start of the time-varying multi-dimensional code. The start frame can be any predetermined frame of code which is unique. Also after the start frame, there can be one or more format frames to indicate the format of the time-varying multi-dimensional code including but not limited to its language and encoding method.

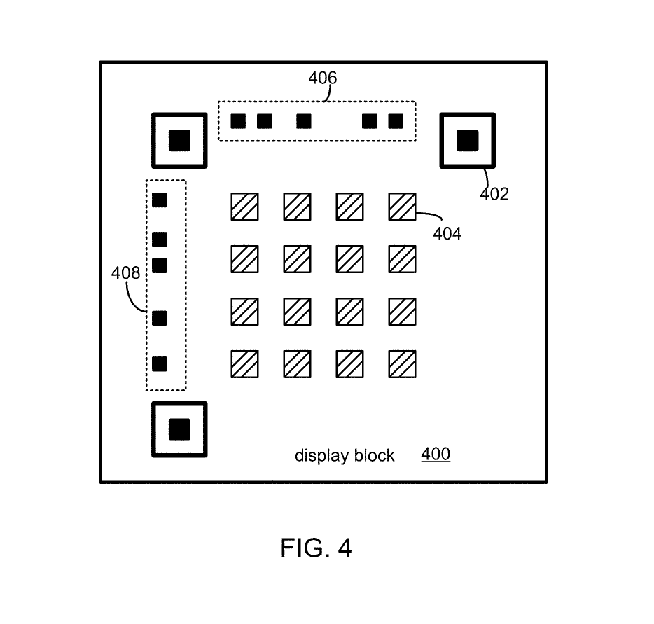

FIG. 4 shows an embodiment of a display block of this invention. In FIG. 4, a display block 400 includes a position detection pattern 402, a version pattern 406 and a error correction level pattern 408. The display block 400 also includes a display element 404 and many other similar display elements. The position detection pattern 402 is a time-invariant pattern to help locate the positions of the display elements and the positions of the version pattern 406 and the error correction level pattern 408. The version pattern 406 is a time-invariant pattern to indicate the version information of the display block 400 including but not limited to: number of display elements; shape of display elements; formation of display elements; color of display elements. In order to avoid the possible error during the code transfer process, an error correction algorithm (for example, Reed-Solomon algorithm) can be used so the code can be recovered even when it contains some errors due to possible dirty display block surface or unwanted light reflection from the display block surface. There can be multiple levels of error correction, and higher the level is the more errors the code can tolerate and recover from them. The error correction level pattern 408 is a time-invariant pattern to indicate the error correction level. Shown in FIG. 4 is only an exemplary embodiment for sake of illustration of the invention. In other embodiments the position detection pattern 402 can be any shape at any locations. The version pattern 406 and error correction level pattern 408 can also be at locations and they can have any number of bits of data. The display block 400 can also have any number of display elements of circle shape, oval shape or any other shape, arranged in any formation.

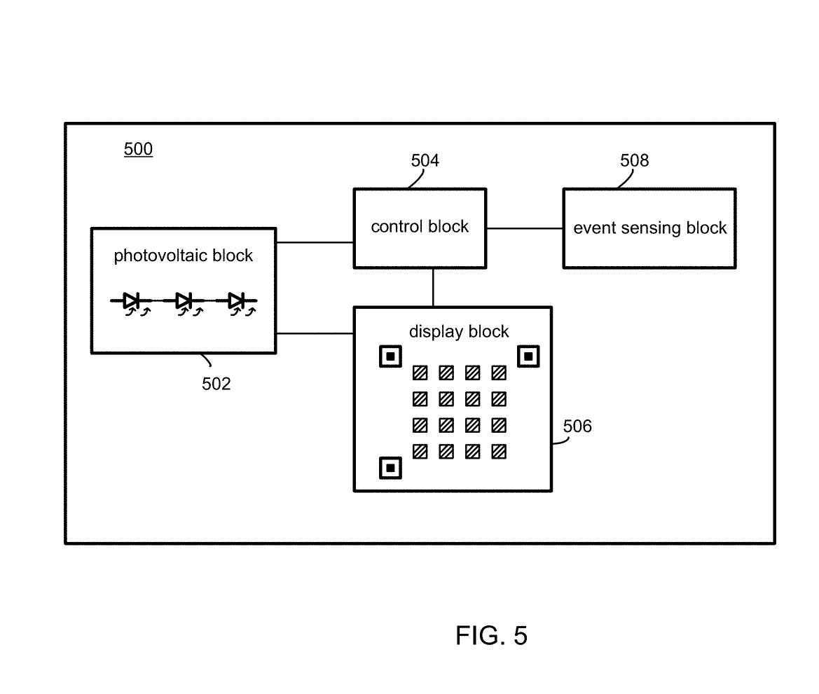

FIG. 5 shows another embodiment of a multi-dimensional code storage and transfer system of this invention. In FIG. 5, a multi-dimensional code storage and transfer system 500 includes a photovoltaic block 502, a control block 504, a display block 506 and an event sensing block 508. The photovoltaic block 502 is coupled to the control block 504 and the display block 506. The control block 504 is also coupled to the display block 506 and the event sensing block 508. In FIG. 5, the photovoltaic block 502 includes one or more printed solar cells and generates electric power for the control block 504, the 106 and the event sensing block 508 when receiving flash light from a smart device. The control block 504 controls the display block 506 to display a time-varying multi-dimensional code. A smart device can capture the time-varying code and decode it by analyzing the captured images. The event sensing block 508 can sense a predetermined event, and let the control block 504 control the display block 506 to display different time-varying multi-dimensional codes based on the sensing result of the event sensing block 508. A typical event to sense can be whether the package of a product has been opened or not.

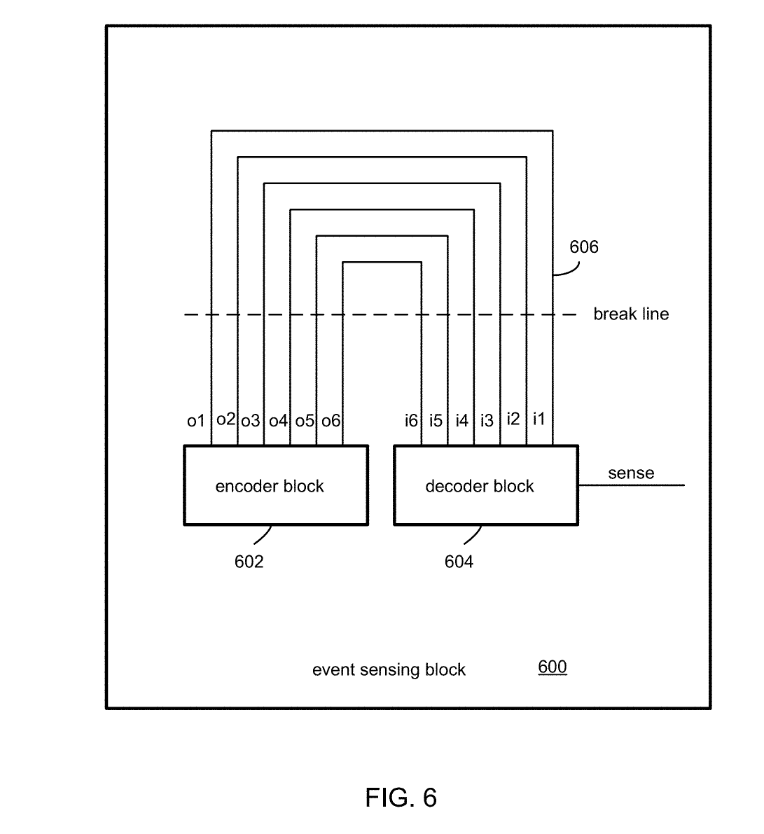

FIG. 6 shows an embodiment of an event sensing block of this invention. In FIG. 6, an event sensing block 600 includes a encoder block 602, a decoder block 604, a conducting wire 606 and many similar conducting wires coupled between the encoder block 602 and the decoder block 604. When the conducting wires are not broken, the input signals i1 to i6 of the decoder block 604 should be the same as the output signals o1 to o6 of the encoder block 602. So the signal sense from the decoder block 604 should be at logic low state. If any of the conducting wires is broken hence the i1 to i6 are not equal to the o1 to o6, the signal sense from the decoder block 604 will be logic high. In practical usage, the event sensing block 600 can be placed to a position that when a package is opened or a lid of bottle is opened, the conducting wires of the event sensing block 600 will be broken along the break line. So the signal sense will change from logic low state to logic high. This will indicate a predetermined event has occurred. Shown in FIG. 6 there are only 5 conducting wires in the exemplary embodiment for sake of illustration of the invention. In other embodiments the event sensing block 600 can have up to hundreds conducting wires. And due the benefit of printed electronics technology, these conducting wires can be printed very narrow and close to each other (up to several micrometers). So when these conducting wires are broken, it is very difficult, if not impossible, to re-connect them in the right way without significant cost. This makes the prospect of a counterfeit much more difficult.

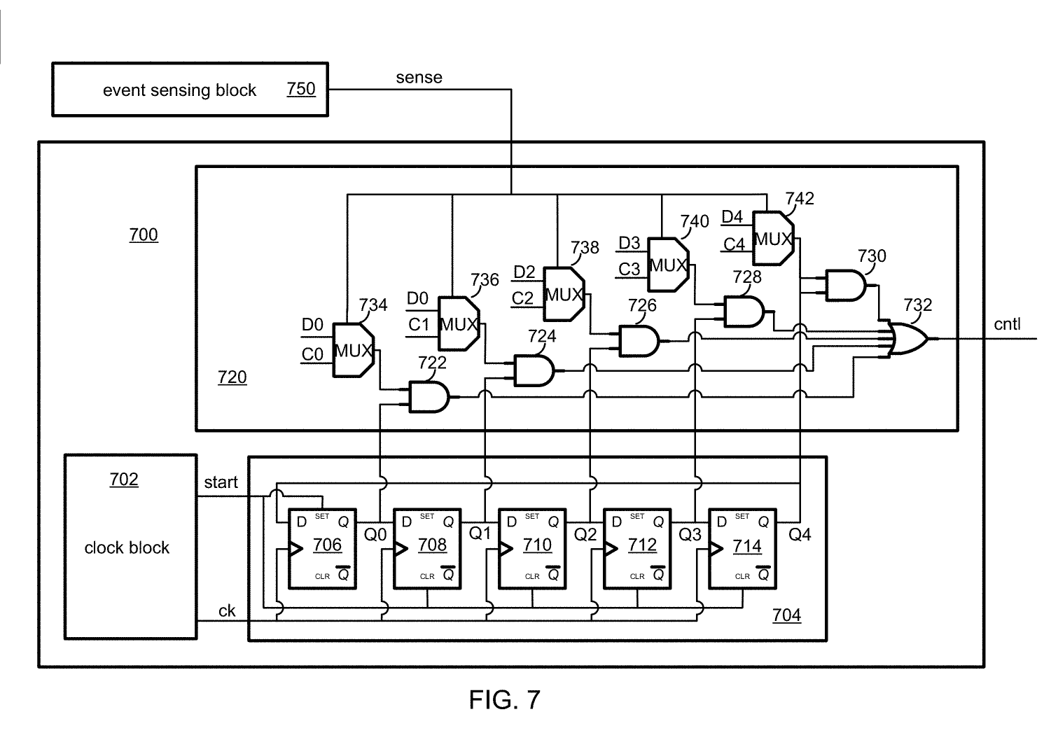

FIG. 7 shows another embodiment of a control block of this invention. In FIG. 7, a control block 700 includes a clock block 702, a ring counter block 704 and a code block 720. The ring counter block 704 includes a D Flip-Flop 706, a D Flip-Flop 708, a D Flip-Flop 710, a712 and a D Flip-Flop 714. The clock block 702 generates a signal start which is coupled to the SET terminal of the D Flip-Flop 706, and the CLR terminals of the D Flip-Flop 708, the D Flip-Flop 710, the D Flip-Flop 712 and the D Flip-Flop 714. The clock block 702 also generates a clock signal ck which is coupled to the input clock terminals of the D Flip-Flop 706, the D Flip-Flop 708, the D Flip-Flop 710, the D Flip-Flop 712 and the D Flip-Flop 714. The code block 720 includes a AND gate 722, a AND gate 724, a AND gate 726, a AND gate 728, a AND gate 730 and a OR gate 732. The outputs of the AND gate 722, the AND gate 724, the AND gate 726, the AND gate 728 and the AND gate 730 are coupled to the inputs of the OR gate 732. The code block 720 also includes a MUX 734, a MUX 736, a MUX 738, a MUX 740 and a MUX 742. In FIG. 7, an event sensing block 750 senses a predetermined event and generate a signal sense. The signal sense is coupled to the MUX 734, the MUX 736, the MUX 738, the MUX 740 and the MUX 742. The code block 720 also includes code signals C0 to C4 and D0 to D4. The code signals C0 to C4 and D0 to D4 are logic high or low signals, which can come from ROM (Read Only Memory) memory, EPROM (Erasable Programmable Read Only Memory) or programmable fuse memory (which can be programmed by using laser zap or high current). When the signal sense is low, the code signals C0 to C4 are connected to the AND gate 722, the AND gate 724, the AND gate 726, the AND gate 728 and the AND gate 730 through the MUX 734, the MUX 736, the MUX 738, the MUX 740 and the MUX 742 respectively. When the signal sense is high, the code signals D0 to D4 are connected the AND gate 722, the AND gate 724, the AND gate 726, the AND gate 728 and the AND gate 730 through the MUX 734, the MUX 736, the MUX 738, the MUX 740 and the MUX 742 respectively. So the event sensing block 750 can sense a predetermined event, and let the control block 700 to control a display block to display different time-varying multi-dimensional codes based on the sensing result of the event sensing block 750.

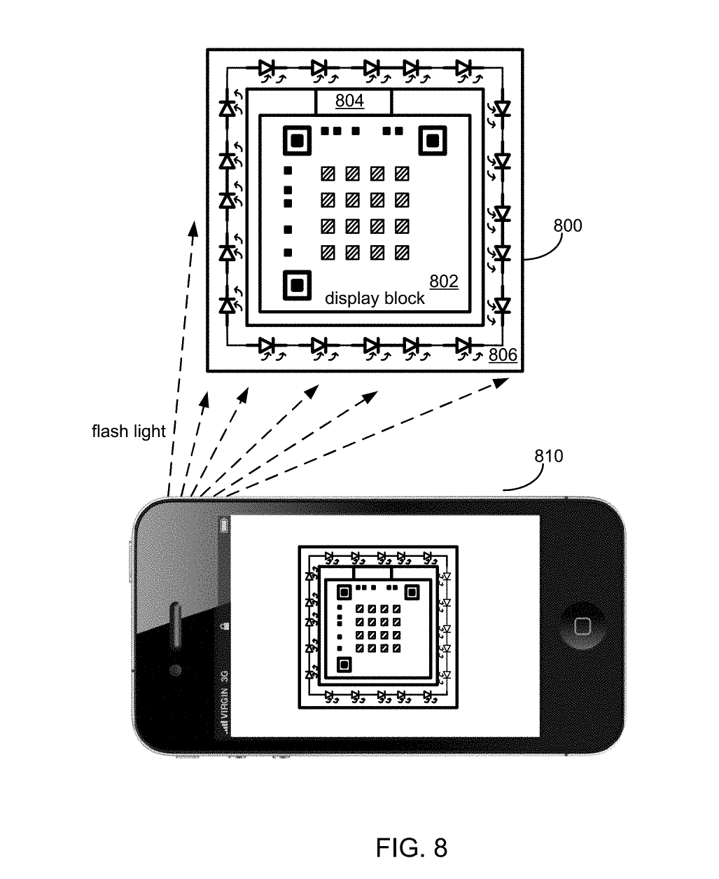

FIG. 8 shows another embodiment of a multi-dimensional code storage and transfer system of this invention. In FIG. 8, a multi-dimensional code storage and transfer system 800 includes a display block 802, a control block 804 and a photovoltaic block 806. The photovoltaic block 806 can be put at side of the display block 802, but in this embodiment the photovoltaic block 806 is put around the display block 802. The control block 804 is usually of very small size due the benefit of printed electronics technology, and is placed at the top side of the display block 802 in this embodiment. In FIG. 8, a smart device 810 sheds flash lights on the photovoltaic block 806, and the photovoltaic block 806 generates electrical power for the control block 804 and the display block 802. The display block 802 displays a time-varying multi-dimensional code which is captured by the smart device 810 using its camera. The smart device 810 analyzes the captured images and decodes the code. A smart device application can be downloaded and installed to the smart device 810 to conduct above operations. The multi-dimensional code storage and transfer system 800 can be made by using printed electronics technology. The display block 802, the control block 804 or the photovoltaic block 806 can also be made using conventional technology such as LCD (Liquid Crystal Display) display, silicon based integrated circuit and solar cell panel, and then integrated together to form the whole system.

While the present disclosure describes several embodiments, these embodiments are to be understood as illustrative and do not limit the claim scope. The structures and methods disclosed in this invention can have many variations and modifications. Having thus described the present invention it will be apparent to one of ordinary skill in the art that various modifications can be made within the spirit and scope of the present invention.

Accordingly, the scope of the invention should be determined not by the embodiments illustrated, but by the appended claims and their legal equivalents.

1. A multi-dimensional code storage and transfer system, comprising:
a display block to display a multi-dimensional code, and,
a control block to control said display block to display different multi-dimensional codes at different times, and,
a photovoltaic block to generate electric power for said display block and said control block from flash light received,
whereby a smart device can shed flash light on said photovoltaic block and read said multi-dimensional code from said display block.

2. The multi-dimensional code storage and transfer system of claim 1 wherein:
said photovoltaic block contains at least one solar cell to generate electric power from flash light.

3. The multi-dimensional code storage and transfer system of claim 1 wherein:
said display block uses OLED or electrochromic or e-ink or electroluminescent display technology or any combinations of them.

4. The multi-dimensional code storage and transfer system of claim 1 wherein:
said display block, said control block or said photovoltaic block is made using printed electronics technology including but not limited to screen printing, flexography, gravure, offset lithography and inkjet.

5. The multi-dimensional code storage and transfer system of claim 1 wherein:
said control block controls said display block to display different multi-dimensional codes every 10 milliseconds to 500 milliseconds.

6. The multi-dimensional code storage and transfer system of claim 1 wherein:
said display block comprises at least one display element of square, circle, oval or other customized shape, to display different multi-dimensional codes by changing the brightness or color or both of at least one of said display elements at different times.

7. The multi-dimensional code storage and transfer system of claim 1 wherein:
said display block comprises position detection pattern or version pattern or error correction level pattern or any combination of them.

8. The multi-dimensional code storage and transfer system of claim 1 wherein:
said display block displays multi-dimensional codes with error correction algorithm to prevent code corruption.

9. The multi-dimensional code storage and transfer system of claim 1 wherein:
said multi-dimensional codes represent an alphanumeric string or a character string or a voice file or an image file or a video file or any combination of them.

10. The multi-dimensional code storage and transfer system of claim 1 wherein:
said photovoltaic block can be put side by side with said display block, or be put around said display block.

11. The multi-dimensional code storage and transfer system of claim 1 wherein:
said control block comprises a clock block, a ring counter block and a code block,
whereby the multi-dimensional codes stored inside said code block are read out and displayed at said display block at different times.

12. The multi-dimensional code storage and transfer system of claim 11 wherein:
said code block stores the multi-dimensional codes using ROM memory or EPROM memory or programmable fuse memory.

13. The multi-dimensional code storage and transfer system of claim 1 further including:
an event sensing block to sense a predetermined event and different time-varying multi-dimensional codes can be displayed accordingly based on the sensing result of said event sensing block.

14. The multi-dimensional code storage and transfer system of claim 13 wherein:
said event sensing block comprises a plurality of conducting wires with width ranging from 1 um to 100 um, which are difficult to be reconnected correctly after being broken in a predetermined event.

15. The multi-dimensional code storage and transfer system of claim 1 wherein:
said display block, said control block and said photovoltaic block are printed on flexible substrates so the whole system can be put on curved surfaces.

16. The multi-dimensional code storage and transfer system of claim 1 wherein:
said display block, said control block or said photovoltaic block is printed using organic or inorganic materials.

17. The multi-dimensional code storage and transfer system of claim 1 wherein:
the time-varying multi-dimensional code displayed by said display block includes a start frame or a format frame.

18. A method to store and transfer multi-dimensional code, comprising steps of:
(a) converting flash light to electric power by a photovoltaic block, to power a control block and a display block, and
(b) displaying a time-varying multi-dimensional code on said display block controlled by said control block,
whereby a smart device can shed flash light on said photovoltaic block, and receive the multi-dimensional code from said display block using its video capture capability.

19. The method to store and transfer multi-dimensional code as claimed in claim 18, wherein:
in step (b) said display block displays the time-varying multi-dimensional code by changing the brightness or color or both of at least one of its display elements at different times.

20. The method to store and transfer multi-dimensional code as claimed in claim 18, before step (b) further including:
(b1) sensing a predetermined event by an event sensing block, and,
(b2) choosing different time-varying multi-dimensional codes based on the sensing result from said event sensing block.
